(19) United States
(12) Patent Application Publication
(10) Pub. No.: US 2011/0316033 A1
(43) Pub. Date: Dec. 29, 2011

(54) LIGHT EMITTING MODULE, METHOD OF MANUFACTURING THE LIGHT EMITTING MODULE, AND LAMP UNIT

(75) Inventors: Shogo Sugimori, Shizuoka (JP); Akihiro Nomura, Shizuoka (JP); Sakaki Morishita, Shizuoka (JP)

(73) Assignee: KOITO MANUFACTURING CO., LTD., Tokyo (JP)

(21) Appl. No.: 13/254,822

(22) PCT Filed: Mar. 5, 2010
(86) PCT No.: PCT/JP2010/001546

§ 371 Date: Sep. 7, 2011

(30) Foreign Application Priority Data
Mar. 5, 2009 (JP) 2009055216

(51) Int. Cl. H01L 33/50

(52) U.S. Cl. 257/98; 438/29; 257/E33.06

(57) ABSTRACT

In a light emitting module, a light wavelength conversion member 60 is formed in a plate shape and converts the wavelength of blue light to emit yellow light. The buffer layer 82 has translucency and is formed on the light wavelength conversion member 60. A semiconductor layer 84 undergoes crystal growth on the buffer layer 82 and is provided to emit blue light by being applied with a voltage. A first electrode 64 is formed on the upper surface of the buffer layer 82. A second electrode 66 is formed on the upper surface of the semiconductor layer 84. The buffer layer 82 is formed of a conductive material and is provided so as to be capable of applying a voltage for light emission to the semiconductor layer 84.

### FIELD OF THE INVENTION

The present invention relates to a light emitting module, a method of manufacturing the light emitting module, and a lamp unit comprising the light emitting module, in particular, to a light emitting module having a light wavelength conversion member that converts the wavelength of the light within a certain wavelength range and emits the light, a method of manufacturing the light emitting module, and a lamp unit comprising the light emitting module.

### BACKGROUND ART

In order to obtain light emitting modules that emit, for example, white light by using light emitting elements, such as LEDs (Light Emitting Diodes), the techniques of using phosphor materials have been actively developed in recent years. For example, it is possible to obtain white light by attaching, to an LED emitting blue light, a phosphor material that is excited by the blue light to emit yellow light. Herein, a structure comprising a ceramic layer arranged within the channel of the light emitted by, for example, a light emitting layer is proposed (see, e.g., Patent Document 1).
[Patent Document 1] Japanese Patent Application Publication No. 2006-5367

### DISCLOSURE OF THE INVENTION

### Problem to be Solved by the Invention

For example, adhesion, or the like, is proposed as a method of attaching, to a light emitting layer, a phosphor material that has been beforehand formed into a plate shape, such as a ceramic layer, in the above Patent Document. However, the adhesion layer can be deteriorated by receiving the light from the light emitting layer. Also, voids can be generated in the adhesion layer, and the presence of the voids can decrease the extraction efficiency of. In addition, the extraction efficiency of light can be decreased by providing an adhesion layer having a relatively low refractive index. In addition, the extraction efficiency of light can be decreased when the light passes through an adhesion layer because the adhesion layer has a light transmittance smaller than 100%. Further, an adhesion process is needed besides a process in which a semiconductor layer undergoes crystal growth on a growth substrate. In addition to that, an expensive substrate for crystal growth, such as sapphire or SiC, is needed besides the phosphor material that has been beforehand formed into a plate shape, such as a ceramic layer.

Also, a technique in which a III-nitride nucleation layer is deposited directly on the ceramic layer at a low temperature and a buffer layer made of GaN is further deposited thereon at a high temperature is proposed in the above Patent Document. According to the Patent Document, it is supposed to be possible to correct an adverse effect by lattice mismatch with many low-temperature intermediate layers being inserted between the substrate and the GaN buffer layer. However, many processes are needed in order to deposit such many layers on the ceramic layer prior to the growth of a light emitting layer, and hence there is room for improvement in terms of enhancing the productivity of light emitting modules.

Accordingly, the present invention has been made to solve the aforementioned problems, and a purpose of the invention is to simplify a production process of light emitting modules in each of which a light wavelength conversion member and a semiconductor layer are combined together.

### Means for Solving the Problems

In order to solve the aforementioned problems, a light emitting module according to an embodiment of the present invention comprises: a plate-shaped light wavelength conversion member configured to convert the wavelength of the light within a certain wavelength range and to emit the light; and a semiconductor layer that undergoes crystal growth on the light wavelength conversion member and is provided so as to emit the light containing at least part of the wavelength range by being applied with a voltage.

According to the embodiment, a process in which a light wavelength conversion member is adhered to a semiconductor layer and a process in which a buffer layer is provided can be omitted; and hence the productivity during the manufacture of light emitting modules can be enhanced. It is noted that the semiconductor layer may undergo crystal growth by an ELO (epitaxial lateral overgrowth) method.

Another embodiment of the present invention is also a light emitting module. The light emitting module comprises: a plate-shaped light wavelength conversion member configured to convert the wavelength of the light within a certain wavelength range and to emit the light; a buffer layer that has been formed on the light wavelength conversion member and has translucency; and a semiconductor layer that undergoes crystal growth on the buffer layer and is provided so as to emit the light containing at least part of the certain wavelength range by being applied with a voltage.

According to the embodiment, a process in which another layer is deposited between a light wavelength conversion member and a buffer layer can be omitted, and hence the productivity during the manufacture of the light emitting modules can be enhanced. It is noted that the semiconductor layer may undergo crystal growth by an ELO method.

The light emitting module according to the aforementioned embodiment of the present invention may further comprise a pair of electrodes that make the semiconductor layer emit light by applying a voltage between them, wherein the pair of electrodes have been formed on one of the surfaces of the semiconductor layer opposite to the surface thereof that has undergone crystal growth to become the light wavelength conversion member.

According to the embodiment, both of the pair of electrodes can be exposed in the same direction, and hence a light emitting module of a so-called flip-chip type can be easily manufactured by, for example, making the pair of electrodes face a sub-mount.

The light emitting module according to the aforementioned embodiment of the present invention may further comprise: a first electrode provided on one of both the surfaces of the semiconductor layer on the same side as the surface thereof that has undergone crystal growth to become the light wavelength conversion member; and a second electrode that is provided on one of both the surfaces of the semiconductor layer opposite to the surface thereof that has undergone crystal growth to become the light wavelength conversion member and that makes the semiconductor layer emit light by applying a voltage between the first electrode and the second electrode. Alternatively, the semiconductor layer may undergo crystal growth on the first electrode.

According to the embodiment, a light emitting module of a so-called vertical chip type can also be manufactured even when a semiconductor layer undergoes crystal growth to become a light wavelength conversion member.

The buffer layer may be formed of a conductive material and be provided so as to be capable of applying a voltage for light emission to the semiconductor layer. According to the embodiment, it becomes possible to appropriately apply a voltage to the semiconductor layer without separately providing a conductive layer on the joint surface with the buffer layer of both the surfaces of the semiconductor layer or within the semiconductor layer. Accordingly, a production process of light emitting modules can be simplified in comparison with the case where a conductive layer is provided separately from the buffer layer.

The light emitting module according to the aforementioned embodiment of the present invention may further comprise: a first electrode provided on one of both the surfaces of the buffer layer on the same side as the surface thereof on which the semiconductor layer has undergone crystal growth; and a second electrode that is provided on one of both the surfaces of the semiconductor layer opposite to the surface thereof that has undergone crystal growth to become the light wavelength conversion member and that makes the semiconductor layer emit light by applying a voltage between the first electrode and the second electrode.

According to the embodiment, it becomes possible to appropriately apply a voltage to the semiconductor layer via the buffer layer by applying a voltage between the first electrode and the second electrode. Further, both of the first electrode and the second electrode can be exposed in the same direction, and hence a light emitting module of a so-called flip-chip type can be easily manufactured by, for example, making the pair of electrodes face a sub-mount.

The light emitting module according to the aforementioned embodiment may further comprise: a first electrode provided on one of both the surfaces of the buffer layer opposite to the surface thereof on which the semiconductor layer has undergone crystal growth; and a second electrode that is provided on one of both the surfaces of the semiconductor layer opposite to the surface thereof that has undergone crystal growth to become the light wavelength conversion member and that makes the semiconductor layer emit light by applying a voltage between the first electrode and the second electrode. Alternatively, the buffer layer may be formed on the first electrode.

According to the embodiment, it becomes possible to appropriately apply a voltage to the semiconductor layer via the buffer layer by applying a voltage between the first electrode and the second electrode even in a light emitting module of a vertical chip type.

The light emitting module according to the aforementioned embodiment may further comprise an electrode that has been provided between the buffer layer and the light wavelength conversion member and that has translucency. According to the embodiment, it becomes possible to apply a voltage to the light wavelength conversion member by using the electrode. Accordingly, it becomes possible to appropriately apply a voltage to the light wavelength conversion member even when, for example, a buffer layer whose conductivity is not high is provided.

Still another embodiment of the present invention is a method of manufacturing a light emitting module. The method comprises making a semiconductor layer that emits the light containing at least part of a certain wavelength range by being applied with a voltage undergo crystal growth on a plate-shaped light wavelength conversion member that converts the wavelength of the light within the certain wavelength range and emits the light.

According to the embodiment, a process in which a light wavelength conversion member is adhered to a semiconductor layer and a process in which a buffer layer is provided can be omitted; and hence the productivity during the manufacture of light emitting modules can be enhanced.

Still another embodiment of the present invention is also a method of manufacturing a light emitting module. The method comprises: forming a buffer layer having translucency on a plate-shaped light wavelength conversion member that converts the wavelength of the light within a certain wavelength range and emits the light; and making a semiconductor layer that emits the light containing at least part of the certain wavelength range by being applied with a voltage undergo crystal growth on the buffer layer.

According to the embodiment, a process in which another layer is deposited between a light wavelength conversion member and a buffer layer can be omitted, and hence the productivity during the manufacture of light emitting modules can be enhanced.

The method may further comprise forming, on one of the surfaces of the semiconductor layer opposite to the surface thereof that has undergone crystal growth to become the light wavelength conversion member, a pair of electrodes that make the semiconductor layer emit light by applying a voltage between them.

According to the embodiment, both of the pair of electrodes can be exposed in the same direction, and hence a light emitting module of a so-called flip-chip type can be easily manufactured by, for example, making the pair of electrodes face a sub-mount.

The method may further comprise: providing a first electrode so as to be adjacent to the light wavelength conversion member; and forming, on one of both the surfaces of the semiconductor layer opposite to the surface thereof that has undergone crystal growth to become the light wavelength conversion member, a second electrode that makes the semiconductor layer emit light by applying a voltage between the first electrode and the second electrode. The making the semiconductor layer undergo crystal growth may include making the semiconductor layer undergo crystal growth on the first electrode.

According to the embodiment, a light emitting module of a so-called vertical chip type can also be manufactured even when a semiconductor layer undergoes crystal growth to become a light wavelength conversion member.

The buffer layer may be formed of a conductive material and be provided so as to be capable of applying a voltage for light emission to the semiconductor layer.

According to the embodiment, it becomes possible to appropriately apply a voltage to the semiconductor layer without separately providing a conductive layer on the joint surface with the buffer layer of both the surfaces of the semiconductor layer or within the semiconductor layer. Accordingly, a production process of light emitting modules can be simplified in comparison with the case where a conductive layer is provided separately from the buffer layer.

The method may further comprise: forming a first electrode on one of both the surfaces of the buffer layer on the same side as the surface thereof on which the semiconductor layer has undergone crystal growth; and forming, on one of both the surfaces of the semiconductor layer opposite to the surface thereof that has undergone crystal growth to become the light wavelength conversion member, a second electrode that makes the semiconductor layer emit light by applying a voltage between the first electrode and the second electrode.

According to the embodiment, it becomes possible to appropriately apply a voltage to the semiconductor layer via the buffer layer by applying a voltage between the first electrode and the second electrode. Further, both of the first electrode and the second electrode can be exposed in the same direction, and hence a light emitting module of a so-called flip-chip type can be easily manufactured by, for example, making the pair of electrodes face a sub-mount.

The method may further comprise: providing a first electrode so as to be adjacent to the light wavelength conversion member; and forming, on one of both the surfaces of the semiconductor layer opposite to the surface thereof that has undergone crystal growth to become the light wavelength conversion member, a second electrode that makes the semiconductor layer emit light by applying a voltage between the first electrode and the second electrode. The forming the buffer layer may include forming the buffer layer on the first electrode.

According to the embodiment, it becomes possible to appropriately apply a voltage to the semiconductor layer via the buffer layer by applying a voltage between the first electrode and the second electrode even in a light emitting module of a vertical chip type.

The method may further comprise forming an electrode having translucency between the buffer layer and the light wavelength conversion member. According to the embodiment, it becomes possible to apply a voltage to the light wavelength conversion member by using the electrode. Accordingly, it becomes possible to appropriately apply a voltage to the light wavelength conversion member even when, for example, a buffer layer whose conductivity is not high is provided.

Still another embodiment of the present invention is a lamp unit. The lamp unit comprises: a light emitting module including a plate-shaped light wavelength conversion member that converts the wavelength of the light within a certain wavelength range and emits the light, and a semiconductor layer that undergoes crystal growth on the light wavelength conversion member and that is provided so as to emit the light containing at least part of the certain wavelength range by being applied with a voltage; and an optical member configured to collect the light emitted from the light emitting module.

According to the embodiment, a lamp unit can be manufactured by using a light emitting module that has been manufactured by a simplified production process. Accordingly, it becomes possible to provide a low-cost lamp unit.

Still another embodiment of the present invention is also a lamp unit. The lamp unit comprises: a light emitting module including a plate-shaped light wavelength conversion member that converts the wavelength of the light within a certain wavelength range and emits the light, a buffer layer that has been formed on the light wavelength conversion member and has translucency, and a semiconductor layer that undergoes crystal growth on the buffer layer and is provided so as to emit the light containing at least part of the certain wavelength range by being applied with a voltage; and an optical member configured to collect the light emitted from the light emitting module.

According to the embodiment, a lamp unit can be manufactured by using a light emitting module that has been manufactured by a simplified production process and in which a semiconductor layer has undergone crystal growth more appropriately. Accordingly, it becomes possible to provide a low-cost lamp unit with good quality.

### Advantage of the Invention

According to the present invention, a production process of light emitting modules in each of which a light wavelength conversion member and a semiconductor layer are combined together can be simplified.

### BRIEF DESCRIPTION OF THE DRAWINGS

FIG. 1 is a sectional view illustrating the configuration of an automotive headlamp according to a first embodiment;

FIG. 2 is a view illustrating the configuration of a light emitting module substrate according to the first embodiment;

FIG. 3 is a sectional view of a light emitting element unit according to the first embodiment;

FIG. 4 is a sectional view of a light emitting element unit according to a second embodiment;

FIG. 5 is a sectional view of a light emitting element unit according to a third embodiment;

FIG. 6 is a sectional view of a light emitting element unit according to a fourth embodiment;

FIG. 7 is a sectional view of a light emitting element unit according to a fifth embodiment;

FIG. 8 is a sectional view of a light emitting element unit according to a sixth embodiment;

FIG. 9 is a view illustrating the configuration of a light emitting module substrate according to a seventh embodiment;

FIG. 10 is a sectional view of a light emitting element unit according to the seventh embodiment;

FIG. 11 is a sectional view of a light emitting element unit according to an eighth embodiment;

FIG. 12 is a sectional view of a light emitting element unit according to a ninth embodiment;

FIG. 13 is a sectional view of a light emitting element unit according to a tenth embodiment;

FIG. 14 is a sectional view of a light emitting element unit according to an eleventh embodiment; and

FIG. 15 is a sectional view of a light emitting element unit according to a twelfth embodiment.

### REFERENCE NUMERALS

10 AUTOMOTIVE HEADLAMP
16 LAMP UNIT
30 PROJECTION LENS
34 REFLECTOR
40 LIGHT EMITTING MODULE
54 LIGHT EMITTING ELEMENT UNIT
60 LIGHT WAVELENGTH CONVERSION MEMBER
62 SEMICONDUCTOR LAYER
64 FIRST ELECTRODE
66 SECOND ELECTRODE
80 LIGHT EMITTING ELEMENT UNIT
82 BUFFER LAYER
84 SEMICONDUCTOR LAYER

### BEST MODE FOR CARRYING OUT THE INVENTION

Preferred embodiments will now be described in detail with reference to accompanying drawings.

### First Embodiment

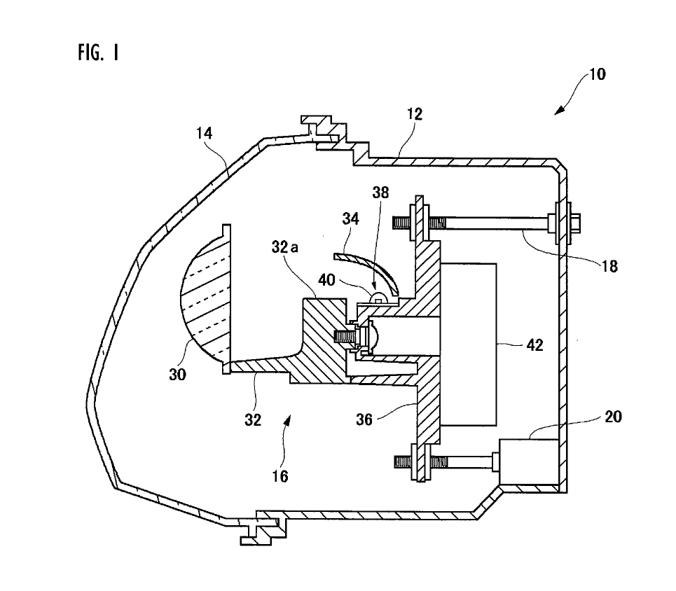

FIG. 1 is a sectional view illustrating the configuration of an automotive headlamp 10 according to a first embodiment. The automotive headlamp 10 has a lamp body 12, a front cover 14, and a lamp unit 16. Hereinafter, descriptions will be made, assuming that the left side in FIG. 1 is the front of the lamp and the right side therein is the back thereof. In addition, when viewing the front of the lamp, the right side is referred to as the right side of the lamp and the left side as the left side thereof. FIG. 1 illustrates the cross section of the automotive headlamp 10 cut by the vertical plane including the light axis of the lamp unit 16, when viewed from the left side of the lamp. When the automotive headlamp 10 is to be mounted in a vehicle, the automotive headlamps 10, which are formed symmetrically with each other, are provided in the left and right front portions of the vehicle, respectively. FIG. 1 illustrates the configuration of either of the left and right automotive headlamps 10.

The lamp body 12 is formed into a box shape having an opening. The front cover 14 is formed into a bow shape with a resin having translucency or glass. The front cover 14 is installed such that the edge thereof is attached to the opening of the lamp body 12. In such a manner, a lamp chamber is formed in the area covered with the lamp body 12 and the front cover 14.

The lamp unit 16 is arranged in the lamp chamber. The lamp unit 16 is fixed to the lamp body 12 with aiming screws 18. The aiming screw 18 in the lower portion is configured to be rotatable by an operation of a leveling actuator 20. Accordingly, the light axis of the lamp unit 16 can be moved in the up-down direction by operating the leveling actuator 20.

The lamp unit 16 has a projection lens 30, a support member 32, a reflector 34, a bracket 36, a light emitting module substrate 38, and a radiating fin 42. The projection lens 30 is composed of a plano-convex aspheric lens, the front surface of which is convex-shaped and the back surface of which is flat-shaped, and projects a light source image that is formed on the back focal plane toward the front of the vehicle as an inverted image. The support member 32 supports the projection lens 30. A light emitting module 40 is provided on the light emitting module substrate 38. The reflector 34 reflects the light emitted from the light emitting module 40 to form the light source image on the back focal plane of the projection lens 30. As stated above, the reflector 34 and the projection lens 30 function as optical members that collect the light emitted by the light emitting module 40 toward the front of the lamp. The radiating fin 42 is installed onto the back surface of the bracket 36 to radiate the heat mainly generated by the light emitting module 40.

A shade 32a is formed on the support member 32. The automotive headlamp 10 is used as a light source for low-beam, and the shade 32a forms, in front of the vehicle, a cut-off line in the light distribution pattern for low-beam by shielding part of the light that has been emitted from the light emitting module 40 and reflected by the reflector 34. Because the light distribution pattern for low-beam is publicly known, descriptions thereof will be omitted.

FIG. 2 is a view illustrating the configuration of the light emitting module substrate 38 according to the first embodiment. The light emitting module substrate 38 has the light emitting module 40, a mounting substrate 44, and a transparent cover 46. The mounting substrate 44 is a printed circuit board, and the light emitting module 40 is attached to the upper surface thereof. The light emitting module 40 is covered with the colorless transparent cover 46 so as to be arranged in the internal space thereof. The light emitting module 40 is configured with a light emitting element unit 54 being attached to a sub-mount 52 via an Au bump 56.

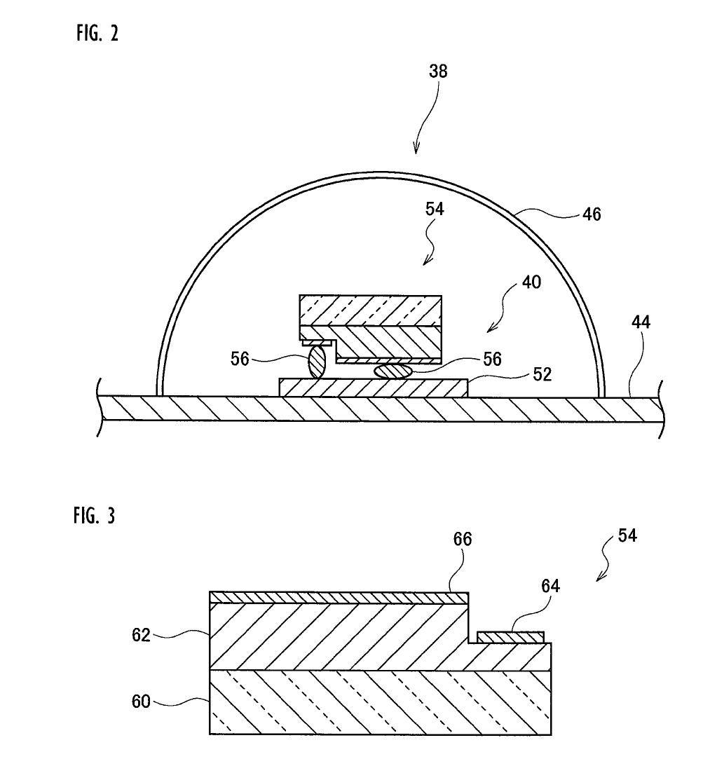

FIG. 3 is a sectional view of the light emitting element unit 54 according to the first embodiment. For easy understanding of a production process of the light emitting element units 54, the light emitting element unit 54 is illustrated vertically oppositely to FIG. 2.

The light emitting element unit 54 has a light wavelength conversion member 60, a semiconductor layer 62, a first electrode 64, and a second electrode 66. The light wavelength conversion member 60 is so-called luminescence ceramic or fluorescent ceramic, and can be obtained by sintering the ceramic green body made of YAG (Yttrium Aluminum Garnet) powder that is a phosphor to be excited by blue light. The light wavelength conversion member 60 thus obtained converts the wavelength of blue light to emit yellow light. The light wavelength conversion member 60 is formed into a plate shape.

In addition, the light wavelength conversion member 60 is formed to be transparent. The “to be transparent” in the first embodiment means that the total light transmittance of the light within the conversion wavelength range is 40 percent or more. As a result of the intensive research and development by the inventors, it has been found that, when the light wavelength conversion member 60 is so transparent that the total light transmittance of the light within the conversion wavelength range is 40 percent or more, the wavelength of light can be appropriately converted by the light wavelength conversion member 60 and a decrease in the light emitted from the light wavelength conversion member 60 can be appropriately suppressed. Accordingly, the light emitted by the semiconductor layer 62 can be more efficiently converted by making the light wavelength conversion member 60 transparent as stated above.

The light wavelength conversion member 60 is composed of an inorganic substance free of an organic binder such that the durability thereof is enhanced in comparison with the case where an organic substance, such as an organic binder, is contained. Accordingly, it becomes possible to supply the power of, for example, 1 W or more to the light emitting module 40, and hence the luminance, light intensity, and luminous flux of the light emitted by the light emitting module 40 can be enhanced.

The semiconductor layer 62 is formed on the light wavelength conversion member 60 by undergoing crystal growth with the use of an epitaxial growth method. The semiconductor layer 62 is provided so as to emit the light containing at least part of a wavelength range by being applied with a voltage. Specifically, an N-type impurity is first doped into GaN such that a semiconductor layer is grown on the light wavelength conversion member 60. Thereby, an N-type semiconductor layer is formed on the light wavelength conversion member 60. Subsequently, a P-type impurity is doped into GaN such that a semiconductor layer is further grown thereon. Alternatively, a quantum well light emitting layer may be provided between the N-type semiconductor layer and the P-type semiconductor layer. An ELO (epitaxial lateral overgrowth) method may be used as the epitaxial growth method.

Crystal growth of these semiconductor layers is achieved by an MOCVD (Metal Organic Chemical Vapor Deposition) method. It is needless to say that a crystal growth method is not limited thereto, and the crystal growth thereof may be achieved by an MBE (Molecular Beam Epitaxy) method.

Subsequently, part of the P-type semiconductor layer is removed by etching to expose part of the upper surface of the N-type semiconductor layer. The first electrode 64 is then formed on the exposed upper surface of the N-type semiconductor layer and the second electrode 66 is formed on the upper surface of the P-type semiconductor layer. Accordingly, the first electrode 64 functions as an N-type electrode and the second electrode 66 as a P-type electrode. Because a method of forming an electrode on a semiconductor layer is well known, descriptions thereof will be omitted. Thus, both of the first electrode 64 and the second electrode 66 are formed on one of the surfaces of the semiconductor layer 62 opposite to the surface thereof that has undergone crystal growth to become the light wavelength conversion member 60.

Finally, the light emitting element unit 54 is provided by being cut into a suitable size with dicing. In the first embodiment, the light emitting element unit 54 is diced into a rectangular shape of 1 mm in length. The semiconductor layer 62 thus formed functions as a semiconductor light emitting element that emits light by being applied with a voltage. According to the first embodiment, a process in which the light wavelength conversion member 60 is adhered to the semiconductor layer 62 and a process in which a buffer layer is provided can be omitted, and hence the productivity during the manufacture of light emitting modules can be enhanced. Further, an expensive sapphire substrate or SiC substrate is not needed, and hence the cost can also be reduced.

The semiconductor layer 62 mainly emits blue light by applying a voltage between the first electrode 64 and the second electrode 66. Specifically, the semiconductor layer 62 is provided such that the central wavelength of the emitted blue light is 470 nm. The light wavelength conversion member 60 converts the wavelength of the light within a wavelength range, which has been mainly emitted by the semiconductor layer 62, and emits the light, so that white light is emitted as synthesized light with the light emitted by the semiconductor layer 62. Alternatively, the semiconductor layer 62 may be provided so as to mainly emit light other than blue light, for example, ultraviolet light.

### Second Embodiment

FIG. 4 is a sectional view of a light emitting element unit 80 according to a second embodiment. Hereinafter, unless otherwise indicated, the configurations of an automotive headlamp 10 and a light emitting module 40 are the same as those of the first embodiment. Hereinafter, the parts similar to the first embodiment will be denoted with the same reference numerals and descriptions thereof will be omitted.

The configuration of the light emitting module 40 according to the second embodiment is the same as that of the first embodiment, except that the light emitting element unit 80 is provided instead of the light emitting element unit 54. The light emitting element unit 80 has a light wavelength conversion member 60, a buffer layer 82, a semiconductor layer 84, a first electrode 64, and a second electrode 66.

It is needed to make the semiconductor layer 84 undergo crystal growth so as to be single-crystalline, while the light wavelength conversion member 60 is poly-crystalline. Accordingly, the buffer layer 82 is formed on the upper surface of the light wavelength conversion member 60 in the second embodiment. The buffer layer 82 functions as a buffer layer for making a semiconductor layer appropriately undergo crystal growth when the lattice constants or coefficients of thermal expansion are different from each other between a substrate and a semiconductor layer to undergo crystal growth thereon.

The buffer layer 82 is formed into a thin film on the upper surface of the light wavelength conversion member 60 by sputtering. Alternatively, vacuum deposition, CVD (Chemical Vapor Deposition), or another film-forming method may be used instead of sputtering. The buffer layer 82 has translucency in which at least part of the light emitted by the semiconductor layer 82 is transmitted. Further, the buffer layer 82 is formed of a conductive material. In the second embodiment, hafnium nitride (HfN) having conductivity is adopted as the material for forming the buffer layer 82. It is noted that a material for forming the buffer layer 82 is not limited thereto, and, for example, GaN, AlN (aluminum nitride), ZnO (zinc oxide) SiC (silicon carbide), ZrB2, or another material may be adopted. For example, the buffer layer 82 may be made by forming an amorphous layer of GaN or AlN at a low temperature, followed by heating thereof.

The semiconductor layer 84 is formed by undergoing crystal growth on the buffer layer 82. In this case, the crystal growth method is the same as that of the semiconductor layer 62 according to the first embodiment. Subsequently, part of the P-type semiconductor layer and that of the N-type semiconductor layer are removed by etching to expose part of the upper surface of the buffer layer 82. The first electrode 64 is then formed on the exposed upper surface of the buffer layer 82, and the second electrode 66 is formed on the upper surface of the P-type semiconductor layer. It is the same as the first embodiment that the light emitting element unit is finally cut into a suitable size with dicing.

In the light emitting element unit 80, the first electrode 64 is formed on one of both the surfaces of the buffer layer 82 on the same side as the surface thereof on which the semiconductor layer 84 has undergone crystal growth, i.e., on the upper surface of the buffer layer 82, as stated above. The second electrode 66 is formed on one of both the surfaces of the semiconductor layer 84 opposite to the surface thereof that has undergone crystal growth to become the light wavelength conversion member 60, i.e., on the upper surface of the semiconductor layer 84. When a voltage is applied between the first electrode 64 and the second electrode 66, the buffer layer 82 applies a voltage for light emission to the semiconductor layer 84. The buffer layer 82 is provided to have higher conductivity than the semiconductor layer 84. By providing the buffer layer 82 on approximately the whole area of the lower surface of the semiconductor layer 84, as stated above, an increase in the forward voltage (Vf) can be suppressed.

The semiconductor layer 84 is the same as the semiconductor layer 62 according to the first embodiment in that the semiconductor layer 84 mainly emits blue light by applying a voltage between the first electrode 64 and the second electrode 66. Alternatively, the semiconductor layer 84 may be provided so as to mainly emit light other than blue light, for example, ultraviolet light.

### Third Embodiment

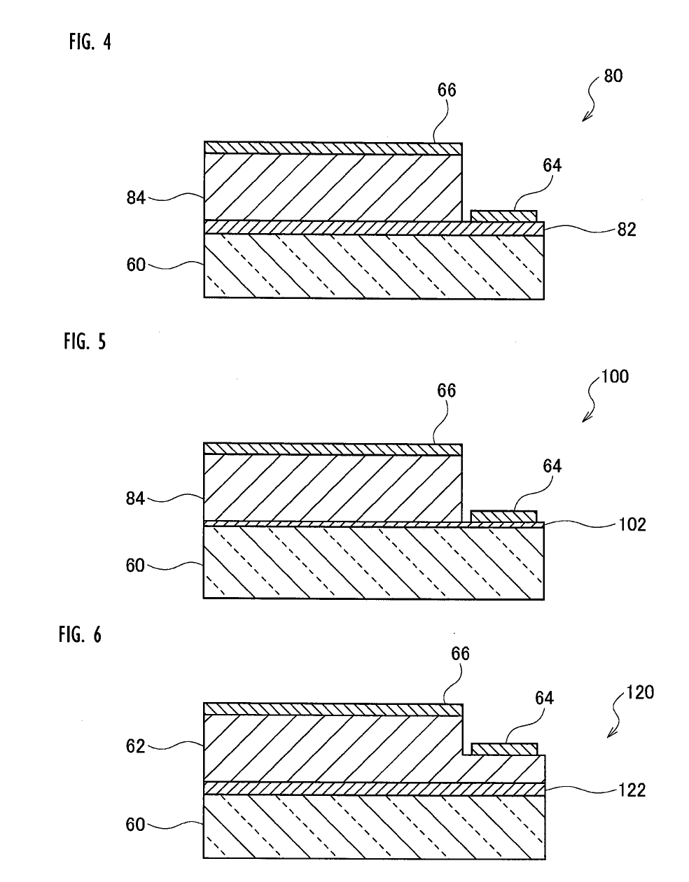

FIG. 5 is a sectional view of a light emitting element unit 100 according to a third embodiment. Hereinafter, unless otherwise indicated, the configurations of an automotive headlamp 10 and a light emitting module 40 are the same as those of the first embodiment. Hereinafter, the parts similar to the aforementioned embodiment will be denoted with the same reference numerals and descriptions thereof will be omitted.

The configuration of the light emitting module 40 according to the third embodiment is the same as that of the first embodiment, except that the light emitting element unit 100 is provided instead of the light emitting element unit 54. The configuration of the light emitting element unit 100 is the same as that of the light emitting element unit 80 according to the first embodiment, except that a buffer layer 102 is provided instead of the buffer layer 82.

In the third embodiment, hafnium nitride having conductivity is adopted as the material for forming the buffer layer 82. It has been made clear from the results of the research and development by the inventors that, although hafnium nitride has conductivity, the translucency thereof is decreased when the thickness thereof is large. Accordingly, the thickness of the buffer layer 102 is made to be greatly small in comparison with the buffer layer 82. By making the thickness of the buffer layer 102 to be small, as stated above, the translucency can be maintained while securing the conductivity. It is needless to say that a material for forming the buffer layer 102 is not limited to hafnium nitride.

### Fourth Embodiment

FIG. 6 is a sectional view of a light emitting element unit 120 according to a fourth embodiment. Hereinafter, unless otherwise indicated, the configurations of an automotive headlamp 10 and a light emitting module 40 are the same as those of the first embodiment. In addition, the parts similar to the aforementioned embodiment will be denoted with the same reference numerals and descriptions thereof will be omitted.

The configuration of the light emitting module 40 according to the fourth embodiment is the same as that of the first embodiment, except that the light emitting element unit 120 is provided instead of the light emitting element unit 54. The light emitting element unit 120 has a light wavelength conversion member 60, a buffer layer 122, a semiconductor layer 62, a first electrode 64, and a second electrode 66. The buffer layer 122 is formed of a material having lower conductivity than the materials of the aforementioned buffer layers 82 and 102. Accordingly, there is the possibility that a voltage may not be fully applied to the semiconductor layer 62 via the buffer layer 122 even if the first electrode 64 is formed directly on the upper surface of the buffer layer 122.

Therefore, the first electrode 64 is formed on the upper surface of the N-type semiconductor layer of the semiconductor layer 62 in the same way as the first embodiment, not formed on the upper surface of the buffer layer 122. Thus, both of the first electrode 64 and the second electrode 66 are formed on one of the surfaces of the semiconductor layer 62 opposite to the surface thereof that has undergone crystal growth to become the buffer layer 122. By providing the first electrode 64 and the second electrode 66 on the semiconductor layer 62, as stated above, it becomes possible to make the semiconductor layer 62 appropriately emit light even when the conductivity of the buffer layer 122 is relatively low.

It is the same as the second embodiment that the buffer layer 122 is formed into a thin film on the upper surface of the light wavelength conversion member 60 by sputtering and that the semiconductor layer 62 undergoes crystal growth on the buffer layer 122 by an epitaxial method. It is the same as the first embodiment that part of the P-type semiconductor layer is then removed by etching to expose part of the upper surface of the N-type semiconductor layer, and where the first electrode 64 and the second electrode 66 are formed. It is also the same as the first embodiment that the light emitting element unit is finally cut into a suitable size with dicing.

### Fifth Embodiment

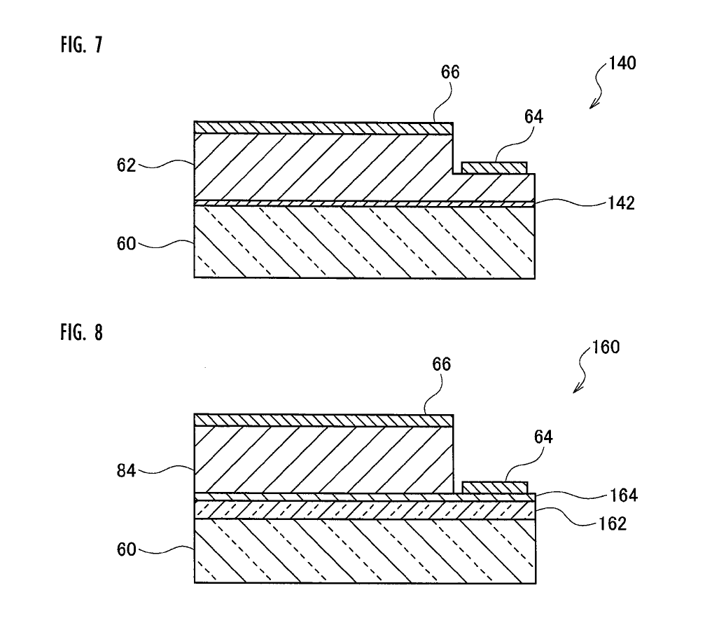

FIG. 7 is a sectional view of a light emitting element unit 140 according to a fifth embodiment. Hereinafter, unless otherwise indicated, the configurations of an automotive headlamp 10 and a light emitting module 40 are the same as those of the first embodiment. In addition, the parts similar to the aforementioned embodiment will be denoted with the same reference numerals and descriptions thereof will be omitted.

The configuration of the light emitting module 40 according to the fifth embodiment is the same as that of the first embodiment, except that the light emitting element unit 140 is provided instead of the light emitting element unit 54. The configuration of the light emitting element unit 140 is the same as that of the light emitting element unit 120 according to the fourth embodiment, except that a buffer layer 142 is provided instead of the buffer layer 122.

In the fifth embodiment, the buffer layer 142 is formed of a material having low conductivity and translucency in comparison with another material that can be adopted. For example, the buffer layer 142 may be formed of a material that has the same translucency as hafnium nitride while having lower conductivity than it. Accordingly, the thickness of the buffer layer 142 is made to be greatly smaller than that of the buffer layer 122. By making the thickness of the buffer layer 142 to be small, as stated above, the translucency of the buffer layer 142 can be enhanced.

### Sixth Embodiment

FIG. 8 is a sectional view of a light emitting element unit 160 according to a sixth embodiment. Hereinafter, unless otherwise indicated, the configurations of an automotive headlamp 10 and a light emitting module 40 are the same as those of the first embodiment. Hereinafter, the parts similar to the aforementioned embodiment will be denoted with the same reference numerals and descriptions thereof will be omitted.

The configuration of the light emitting module 40 according to the sixth embodiment is the same as that of the first embodiment, except that the light emitting element unit 160 is provided instead of the light emitting element unit 54. The light emitting element unit 160 has a light wavelength conversion member 60, a transparent electrode 162, a buffer layer 164, a semiconductor layer 84, a first electrode 64, and a second electrode 66.

In the sixth embodiment, the transparent electrode 162 is first provided on the upper surface of the light wavelength conversion member 60. ITO (Indium Tin Oxide) is adopted for the transparent electrode 162. Alternatively, zinc oxide, tin oxide, or another material may be adopted instead of ITO. The transparent electrode 162 is formed into a film on the upper surface of the light wavelength conversion member 60 by sputtering. Alternatively, a vacuum deposition method or another film-forming method may be used instead of sputtering.

The buffer layer 164 is formed into a thin film on the upper surface of the transparent electrode 162. The method of forming the buffer layer 164 into a film is the same as what has been stated above. Subsequently, part of the P-type semiconductor layer and that of the N-type semiconductor layer are removed by etching to expose part of the upper surface of the buffer layer 164. The first electrode 64 is then formed on the exposed upper surface of the buffer layer 164, and the second electrode 66 is formed on the upper surface of the P-type semiconductor layer. Thus, the first electrode 64 is formed on one of both the surfaces of the buffer layer 164 on the same side as the surface thereof on which the semiconductor layer 84 has undergone crystal growth, i.e., on the upper surface of the buffer layer 164. The second electrode 66 is formed on one of both the surfaces of the semiconductor layer 84 opposite to the surface thereof that has undergone crystal growth to become the light wavelength conversion member 60, i.e., on the upper surface of the semiconductor layer 84.

It is the same as the first embodiment that the light emitting element unit is finally cut into a suitable size with dicing. Alternatively, part of the P-type semiconductor layer, that of the N-type semiconductor layer, and that of the buffer layer 164 may be removed by etching to expose the upper surface of the transparent electrode 162. The first electrode 64 may be formed on the exposed upper surface of the transparent electrode 162.

Although the buffer layer 164 has the same translucency as, for example, the aforementioned buffer layers 82 and 102, the buffer layer 164 is formed, with a material having lower conductivity than the buffer layers 82 and 102, into a greatly thinner film than the buffer layer 82 according to the second embodiment and the buffer layer 102 according to the third embodiment. Accordingly, the transparent electrode 162 has, with the buffer layer 164, the function of applying a voltage to the semiconductor layer 84 between the transparent electrode 162 and the second electrode 66. By providing the transparent electrode 162, as stated above, it becomes possible to appropriately apply a voltage to the semiconductor layer 84. Alternatively, the buffer layer 164 may be formed of a material having low translucency in comparison with another material that can be adopted.

### Seventh Embodiment

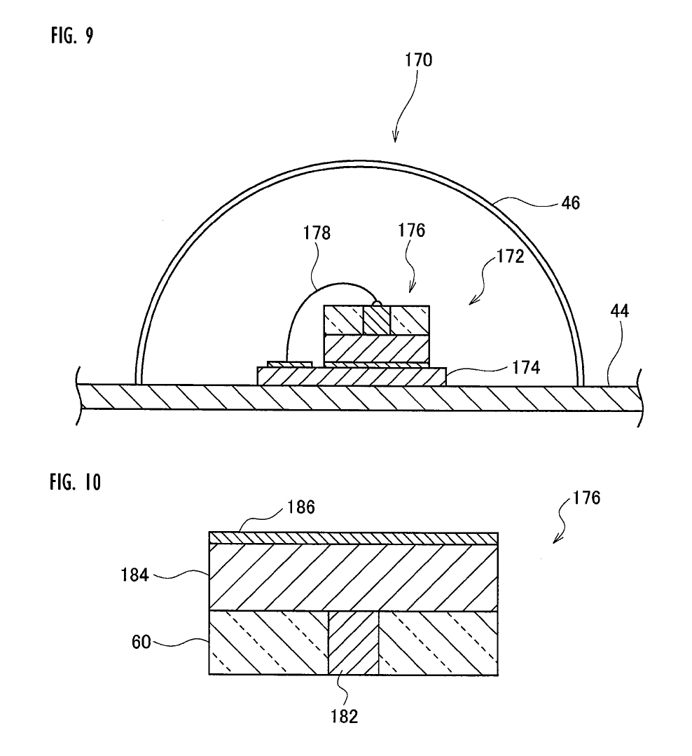

FIG. 9 is a view illustrating the configuration of a light emitting module substrate 170 according to a seventh embodiment. Hereinafter, unless otherwise indicated, the configuration of an automotive headlamp is the same as that of the first embodiment. In addition, the parts similar to the aforementioned embodiment will be denoted with the same reference numerals and descriptions thereof will be omitted.

The configuration of an automotive headlamp according to the seventh embodiment is the same as that of the automotive headlamp 10 according to the first embodiment, except that the light emitting module substrate 170 is provided instead of the light emitting module substrate 38. The light emitting module substrate 170 has a light emitting module 172, a transparent cover 46, and amounting substrate 44. The light emitting module 172 has a sub-mount 174, a light emitting element unit 176, and a conductive wire 178. The light emitting module 172 is attached to part of the upper surface of the sub-mount 174, and is connected to another portion of the upper surface of the sub-mount 174 after the conductive wire 178 has been further bonded to the light emitting module 174. An Au wire, aluminum wire, copper foil, or aluminum ribbon wire may be used for the conductive wire 178.

FIG. 10 is a sectional view of the light emitting element unit 176 according to the seventh embodiment. For easy understanding of a production process of the light emitting element units 176, the light emitting element unit 176 is illustrated vertically oppositely to FIG. 9. Hereinafter, the parts similar to the aforementioned embodiment will be denoted with the same reference numerals and descriptions thereof will be omitted.

The light emitting element unit 176 has a light wavelength conversion member 60, a built-in electrode 182, a semiconductor layer 184, and an electrode 186. In the light emitting element unit 176, the built-in electrode 182 has been beforehand installed in the light wavelength conversion member 60. The light wavelength conversion member 60 is provided with a through-hole through which the built-in electrode 182 is inserted. At the time, the built-in electrode 182 is inserted through the through-hole such that the upper surface of the built-in electrode 182 and that of the light wavelength conversion member 60 form an approximately same plane. Alternatively, the built-in electrode 182 may be arranged to be adjacent to the light wavelength conversion member 60.

The semiconductor layer 184 is formed on the light wavelength conversion member 60 by crystal growth. Accordingly, the semiconductor layer 184 is also formed on the built-in electrode 182 by crystal growth. The material and crystal growth method of the semiconductor layer 184 are the same as, for example, those of the semiconductor layer 62 according to the first embodiment. By making the semiconductor layer 184 undergo crystal growth directly on the upper surface of the light wavelength conversion member 60, as stated above, a process in which the light wavelength conversion member 60 is adhered to the semiconductor layer 184 and a process in which a buffer layer is provided can be omitted.

When the crystal growth of the semiconductor layer 184 is completed, the electrode 186 is then formed on the one of both the surfaces of the semiconductor layer 184 opposite to the surface thereof that has undergone crystal growth to become the light wavelength conversion member 60, i.e., on the upper surface of the semiconductor layer 184. Because the built-in electrode 182 is provided near to the N-type semiconductor layer, it functions as an N-type electrode. Because the electrode 186 is provided near to the P-type semiconductor layer, it functions as a P-type electrode. Thus, it becomes possible to make the semiconductor layer 184 emit light by applying a voltage between the built-in electrode 182 and the electrode 186.

The semiconductor layer 184 is the same as the semiconductor layer 62 according to the first embodiment in that the semiconductor layer 184 mainly emits blue light by applying a voltage between the built-in electrode 182 and the electrode 186. Alternatively, the semiconductor layer 184 may be provided so as to mainly emit light other than blue light, for example, ultraviolet light.

### Eighth Embodiment

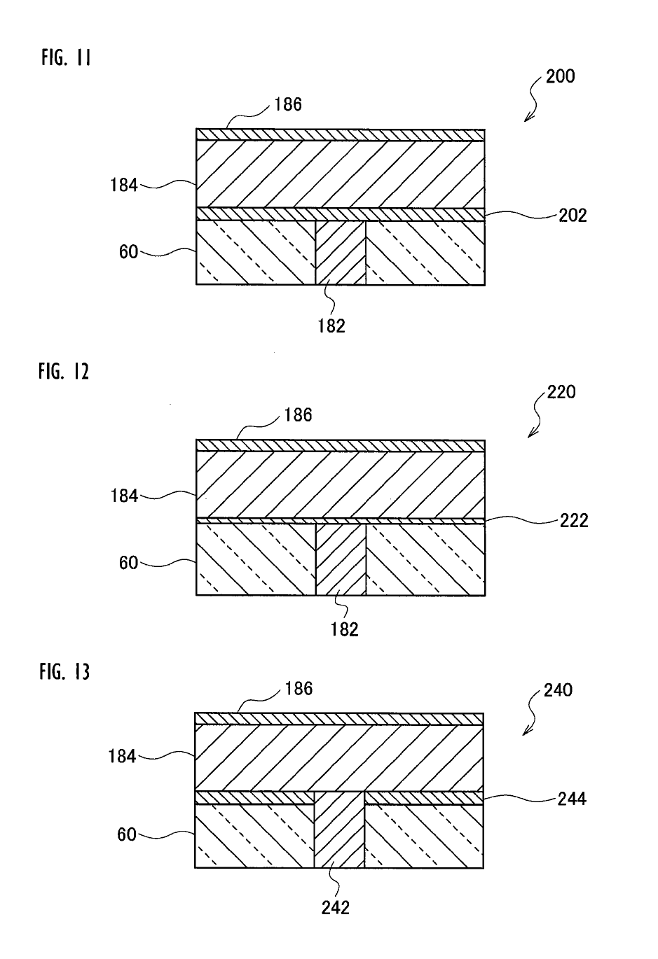

FIG. 11 is a sectional view of a light emitting element unit 200 according to an eighth embodiment. Hereinafter, the parts similar to the aforementioned embodiment will be denoted with the same reference numerals and descriptions thereof will be omitted.

The configuration of a light emitting module according to the eighth embodiment is the same as that of the light emitting module 172 according to the seventh embodiment, except that the light emitting element unit 200 is provided instead of the light emitting element unit 176. The light emitting element unit 200 has a light wavelength conversion member 60, a buffer layer 202, a semiconductor layer 184, a built-in electrode 182, and an electrode 186. The buffer layer 202 is formed into a film on the upper surface of the light wavelength conversion member 60. Accordingly, the buffer layer 202 is also formed into a film on the upper surface of the built-in electrode 182. The material and film-forming method of the buffer layer 202 are the same as, for example, those of the semiconductor layer 62 according to the first embodiment.

The semiconductor layer 184 is formed on the upper surface of the buffer layer 202 by crystal growth. The material and crystal growth method of the semiconductor layer 184 are the same as, for example, those of the semiconductor layer 62 according to the first embodiment. By providing the buffer layer 202, as stated above, the single-crystalline semiconductor layer 184 can appropriately undergo crystal growth on the poly-crystalline light wavelength conversion member 60. It is the same as the first embodiment that the light emitting element unit is finally cut into a suitable size with dicing.

The buffer layer 202 has translucency. In addition, the buffer layer 202 is formed of a conductive material. In the eighth embodiment, the buffer layer 202 is formed of, for example, the same material as that of the buffer layer 82 according to the second embodiment. By forming the buffer layer 202 with a conductive material, as stated above, it becomes possible to apply a voltage to the semiconductor layer 184 by using approximately the whole area of both the surfaces of the semiconductor layer 184. Accordingly, an increase in the forward voltage (Vf) can be suppressed.

### Ninth Embodiment

FIG. 12 is a sectional view of a light emitting element unit 220 according to a ninth embodiment. Hereinafter, the parts similar to the aforementioned embodiment will be denoted with the same reference numerals and descriptions thereof will be omitted.

The configuration of a light emitting module according to the ninth embodiment is the same as that of the light emitting module 172 according to the seventh embodiment, except that the light emitting element unit 220 is provided instead of the light emitting element unit 176. The configuration of the light emitting element unit 220 is the same as that of the light emitting element unit 200 according to the eighth embodiment, except that a buffer layer 222 is provided instead of the buffer layer 202.

In the ninth embodiment, hafnium nitride is adopted as the material for forming the buffer layer 202. It has been made clear from the results of the research and development by the inventors that, although hafnium nitride has conductivity, the translucency thereof is decreased when the thickness thereof is large. Accordingly, the thickness of the buffer layer 222 is made to be greatly small in comparison with the buffer layer 202. By making the thickness of the buffer layer 222 to be small, as stated above, the translucency can be maintained while securing the conductivity. It is needless to say that a material for forming the buffer layer 222 is not limited to hafnium nitride.

### Tenth Embodiment

FIG. 13 is a sectional view of a light emitting element unit 240 according to a tenth embodiment. Hereinafter, the parts similar to the aforementioned embodiment will be denoted with the same reference numerals and descriptions thereof will be omitted.

The configuration of a light emitting module according to the tenth embodiment is the same as that of the light emitting module 172 according to the seventh embodiment, except that the light emitting element unit 240 is provided instead of the light emitting element unit 176. The light emitting element unit 240 has a light wavelength conversion member 60, a buffer layer 244, a semiconductor layer 184, a built-in electrode 242, and an electrode 186. In the light emitting element unit 240, the built-in electrode 182 has been beforehand installed in the light wavelength conversion member 60. The light wavelength conversion member 60 is provided with a through-hole through which the built-in electrode 242 is inserted. At the time, the built-in electrode 242 is inserted through the through-hole so as to protrude from the upper surface of the light wavelength conversion member 60 by an amount approximately the same as the thickness of the buffer layer 244 to be formed. Alternatively, the built-in electrode 182 may be arranged to be adjacent to the light wavelength conversion member 60.

The buffer layer 244 is formed into a film on the upper surface of the light wavelength conversion member 60. The material and film-forming method of the buffer layer 244 are the same as, for example, those of the buffer layer 82 according to the second embodiment. In this case, the upper surface of the built-in electrode 242 is beforehand masked prior to the formation of the buffer layer 244 to avoid the formation of the buffer layer 244 on the upper surface thereof, followed by removal of the masking after the formation of the buffer layer 244. Thus, the upper surface of the built-in electrode 242 is exposed on approximately the same plane as the upper surface of the buffer layer 244.

The semiconductor layer 184 is formed on the upper surface of the buffer layer 244 by crystal growth. Accordingly, the semiconductor layer 184 is also formed on the upper surface of the built-in electrode 242 by crystal growth. The material and crystal growth method of the semiconductor layer 184 are the same as, for example, those of the semiconductor layer 62 according to the first embodiment. The buffer layer 244 is formed of a material having lower conductivity than, for example, the buffer layer 202 according to the eighth embodiment.

Because the built-in electrode 242 is not single-crystalline, there is also the possibility that the semiconductor layer 184 may not appropriately undergo single-crystal growth above the built-in electrode 242 and accordingly light may not be fully emitted in comparison with other areas. However, the upper portion of the built-in electrode in FIG. 13 becomes an area where light is shielded by the built-in electrode 182 during lighting. Accordingly, the influence by the above possibility is small even if the light-emitting amount of this area becomes small.

By providing the built-in electrode 242 and the buffer layer 244, as stated above, it first becomes possible that the semiconductor layer 184 appropriately undergoes crystal growth via the buffer layer 244 on an area where light should be appropriately emitted. Further, even when the buffer layer 244 is formed of a material having low conductivity, it also becomes possible to appropriately apply a voltage to the semiconductor layer 184 by making the semiconductor layer 184 undergo crystal growth directly on the built-in electrode 242 on an area where an influence by a decrease in light-emitting amount is small.

### Eleventh Embodiment

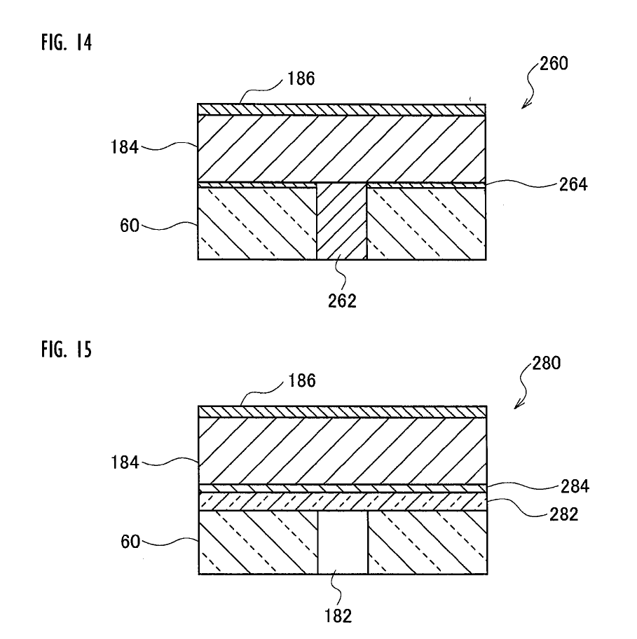

FIG. 14 is a sectional view of a light emitting element unit 260 according to an eleventh embodiment. Hereinafter, the parts similar to the aforementioned embodiment will be denoted with the same reference numerals and descriptions thereof will be omitted.

The configuration of a light emitting module according to the eleventh embodiment is the same as that of the light emitting module 172 according to the seventh embodiment, except that the light emitting element unit 260 is provided instead of the light emitting element unit 176. The configuration of the light emitting element unit 260 is the same as that of the light emitting element unit 240 according to the tenth embodiment, except that a built-in electrode 262 is provided instead of the built-in electrode 242 and a buffer layer 264 is provided instead of the buffer layer 244.

In the eleventh embodiment, the buffer layer 264 is formed of a material having low conductivity and translucency in comparison with another material that can be adopted. For example, the buffer layer 264 may be formed of a material that has the same translucency as hafnium nitride while having lower conductivity than it. Accordingly, the thickness of the buffer layer 264 is made to be greatly smaller than that of the buffer layer 122. By making the thickness of the buffer layer 264 to be small, as stated above, the translucency of the buffer layer 264 can be enhanced.

The built-in electrode 262 is inserted through the through-hole of the light wavelength conversion member 60 so as to protrude from the upper surface of the light wavelength conversion member 60 by an amount approximately the same as the thickness of the buffer layer 264 to be formed. Thus, the built-in electrode 262 is also provided such that the upper surface thereof is exposed on approximately the same plane as the upper surface of the buffer layer 264 in the eleventh embodiment.

### Twelfth Embodiment

FIG. 15 is a sectional view of a light emitting element unit 280 according to a twelfth embodiment. Hereinafter, the parts similar to the aforementioned embodiment will be denoted with the same reference numerals and descriptions thereof will be omitted.

The configuration of a light emitting module according to the twelfth embodiment is the same as that of the light emitting module 172 according to the seventh embodiment, except that the light emitting element unit 280 is provided instead of the light emitting element unit 176. The light emitting element unit 280 has a light wavelength conversion member 60, a transparent electrode 282, a buffer layer 284, a semiconductor layer 184, a built-in electrode 182, and an electrode 186. In the twelfth embodiment, the transparent electrode 282 is first provided on the upper surface of the light wavelength conversion member 60. The material and film-forming method of the transparent electrode 282 are the same as those of the aforementioned transparent electrode 162.

The buffer layer 284 is formed into a thin film on the upper surface of the transparent electrode 282. The buffer layer 284 has translucency. On the other hand, the buffer layer 284 is formed of a material having low conductivity in comparison with another material that can be adopted. For example, the buffer layer 284 may be formed of a material having lower conductivity than hafnium nitride. The film-forming method of the buffer layer 284 is the same as what has been stated above. The buffer layer 284 may be formed of a material having low translucency in comparison with another material that can be adopted.

By providing the transparent electrode 282, as stated above, it becomes possible to apply a voltage to approximately the whole area of the semiconductor layer 284 via the transparent electrode 282 even when the buffer layer 284 is formed of a material having low conductivity. It is the same as the first embodiment that the light emitting element unit is finally cut into a suitable size with dicing.

The present invention should not be limited to the above embodiments, and variations in which each component of the embodiments is appropriately combined are also effective as embodiments of the invention. Various modifications, such as design modifications, can be made with respect to the above embodiments based on the knowledge of those skilled in the art. Such modified embodiments can also fall in the scope of the invention. Hereinafter, such variations will be described.

In a variation, a laminated body in which multiple plate-shaped light wavelength conversion members have been laminated is provided instead of the light wave length conversion member in each of the above embodiments. Each of the multiple light wavelength conversion members included in the laminated body is provided so as to convert the wavelength of the light within a certain wavelength range and emit the light within a wavelength range different from others.

For example, a semiconductor layer is provided so as to emit ultraviolet light by being applied with a voltage. The laminated body is provided such that, in the order of distance from the semiconductor layer, a first light wavelength conversion member, a second light wavelength conversion member, and a third light wavelength conversion member are laminated. The first light wavelength conversion member is provided so as to emit blue light by converting the wavelength of the light within a certain wavelength range among the ultraviolet light. The second light wavelength conversion member is provided so as to emit green light by converting the wavelength of the light within a certain wavelength range among the ultraviolet light. The third light wavelength conversion member is provided so as to emit red light by converting the wavelength of the light within a certain wavelength range among the ultraviolet light. It is needless to say that the order of lamination and the number of laminations of the first to third light wavelength conversion members are not limited to what have been stated above. Also, it is needless to say that the light emitted by the semiconductor layer is not limited to ultraviolet light and that the property and the shape of each of the first to third light wavelength conversion members are also not limited to what have been stated above.

Thus, a light emitting module that converts the light emitted by a semiconductor layer into blue light, green light, and red light, and then emits synthesized light thereof, i.e., white light can be provided. Further, various color light can be emitted by laminating multiple light wavelength conversion members each having a wavelength conversion property different from others.

In another variation, a light wavelength conversion member is provide as a joint body of multiple light wavelength conversion members that have been arranged so as to be extended in a plate-shaped manner in each of the above embodiments. For example, the semiconductor layer is provided so as to emit ultraviolet light by being applied with a voltage. Each of the multiple light wavelength conversion members is provide so as to emit light different from others by converting the wavelength of the light within a certain wavelength range among the ultraviolet light. The multiple light wavelength conversion members may include, for example, the aforementioned first to third light wavelength conversion members. Thereby, a light emitting module that emits white light as synthesized light can be provided. Each of the multiple light wavelength conversion members may be formed into, for example, a triangular shape, quadrangular shape, or hexagonal shape, and may be arranged in an approximately uniform mosaic pattern so as to be extended in a plate-shaped manner. It is needless to say that the light emitted by the semiconductor layer is not limited to ultraviolet light and that the property and the shape of each of the multiple light wavelength conversion members are also not limited to what have been stated above.

In another variation, a light wavelength conversion member may include multiple types of light wavelength conversion materials, i.e., phosphor materials in each of the above embodiments. For example, a semiconductor layer is provided so as to emit ultraviolet light by being applied with a voltage. The light wavelength conversion member includes a first light wavelength conversion material, a second light wavelength conversion material, and a third light wavelength conversion material. The first light wavelength conversion material is provided so as to emit blue light by converting the wavelength of the light within a certain wavelength range among the ultraviolet light. The second light wavelength conversion material is provided so as to emit green light by converting the wavelength of the light in a certain wavelength range among the ultraviolet light. The third light wavelength conversion material is provided so as to emit red light by converting the wavelength of the light within a certain wavelength range among the ultraviolet light. It is needless to say that the light emitted by the semiconductor layer is not limited to ultraviolet light and that the property and the shape of each of the first to third light wavelength conversion materials are also not limited to what have been stated above.

Thereby, a light emitting module that converts the ultraviolet light emitted by a semiconductor layer into blue light, green light, and red light, and then emits synthesized light thereof, i.e., white light can also be provided. Further, various color light can be emitted by containing multiple light wavelength conversion materials each having a wavelength conversion property different from others.

### INDUSTRIAL APPLICABILITY

The present invention relates to a light emitting module, a method of manufacturing the light emitting module, and a lamp unit comprising the light emitting module. In particular, the invention is applicable to a light emitting module having a light wavelength conversion member that converts the wavelength of the light within a certain wavelength range and emits the light, a method of manufacturing the light emitting module, and a lamp unit comprising the light emitting module.

1. A light emitting module comprising:
a plate-shaped light wavelength conversion member configured to convert the wavelength of the light within a certain wavelength range and to emit the light; and
a semiconductor layer that undergoes crystal growth on the light wavelength conversion member and is provided so as to emit the light containing at least part of the wavelength range by being applied with a voltage.

2. (canceled)

3. The light emitting module according to claim 1, wherein
the semiconductor layer undergoes crystal growth by an ELO (epitaxial lateral overgrowth) method.

4. The light emitting module according to claim 1 further comprising a pair of electrodes that have been formed on one of the surfaces of the semiconductor layer opposite to the surface thereof that has undergone crystal growth to become the light wavelength conversion member and that make the semiconductor layer emit light by applying a voltage between them and that make the semiconductor layer emit light by applying a voltage between them.

5. The light emitting module according to claim 1 further comprising:
a first electrode provided on one of both the surfaces of the semiconductor layer on the same side as the surface thereof that has undergone crystal growth to become the light wavelength conversion member; and
a second electrode that is provided on one of both the surfaces of the semiconductor layer opposite to the surface thereof that has undergone crystal growth to become the light wavelength conversion member and that makes the semiconductor layer emit light by applying a voltage between the first electrode and the second electrode, wherein
the semiconductor layer undergoes crystal growth on the first electrode.

6-9. (canceled)

10. A method of manufacturing a light emitting module comprising making a semiconductor layer that emits the light containing at least part of a certain wavelength range by being applied with a voltage undergo crystal growth on a plate-shaped light wavelength conversion member that converts the wavelength of the light within the certain wavelength range and emits the light.

11. (canceled)

12. The method of manufacturing a light emitting module according to claim 10 further comprising forming, on one of the surfaces of the semiconductor layer opposite to the surface thereof that has undergone crystal growth to become the light wavelength conversion member, a pair of electrodes that make the semiconductor layer emit light by applying a voltage between them.

13. The method of manufacturing a light emitting module according to claim 10 further comprising:
providing a first electrode so as to be adjacent to the light wavelength conversion member; and
forming, on one of both the surfaces of the semiconductor layer opposite to the surface thereof that has undergone crystal growth to become the light wavelength conversion member, a second electrode that makes the semiconductor layer emit light by applying a voltage between the first electrode and the second electrode, wherein
the making the semiconductor layer undergo crystal growth includes making the semiconductor layer undergo crystal growth on the first electrode.

14-17. (canceled)

18. A lamp unit comprising:
a light emitting module including a plate-shaped light wavelength conversion member that converts the wavelength of the light within a certain wavelength range and emits the light, and a semiconductor layer that undergoes crystal growth on the light wavelength conversion member and that is provided so as to emit the light containing at least part of the certain wavelength range by being applied with a voltage; and
an optical member configured to collect the light emitted from the light emitting module.

19. A lamp unit comprising:
a light emitting module including a plate-shaped light wavelength conversion member that converts the wavelength of the light within a certain wavelength range and emits the light, a buffer layer that has been formed on the light wavelength conversion member and has translucency, and a semiconductor layer that undergoes crystal growth on the buffer layer and is provided so as to emit the light containing at least part of the certain wavelength range by being applied with a voltage; and
an optical member configured to collect the light emitted from the light emitting module.

20. A light emitting module comprising:
a plate-shaped light wavelength conversion member configured to convert the wavelength of the light within a certain wavelength range and to emit the light;
a buffer layer that has been formed on the light wavelength conversion member and has translucency; and
a semiconductor layer that undergoes crystal growth on the buffer layer and is provided so as to emit the light containing at least part of the certain wavelength range by being applied with a voltage.

21. The light emitting module according to claim 20, wherein
the semiconductor layer undergoes crystal growth by an ELO (epitaxial lateral overgrowth) method.

22. The light emitting module according to claim 20 further comprising a pair of electrodes that have been formed on one of the surfaces of the semiconductor layer opposite to the surface thereof that has undergone crystal growth to become the light wavelength conversion member and that make the semiconductor layer emit light by applying a voltage between them.

23. The light emitting module according to claim 20 further comprising:
a first electrode provided on one of both the surfaces of the semiconductor layer on the same side as the surface thereof that has undergone crystal growth to become the light wavelength conversion member; and
a second electrode that is provided on one of both the surfaces of the semiconductor layer opposite to the surface thereof that has undergone crystal growth to become the light wavelength conversion member and that makes the semiconductor layer emit light by applying a voltage between the first electrode and the second electrode, wherein
the semiconductor layer undergoes crystal growth on the first electrode.

24. The light emitting module according to claim 20, wherein
the buffer layer is formed of a conductive material and is provided so as to be capable of applying a voltage for light emission to the semiconductor layer.

25. The light emitting module according to claim 24 further comprising:
a first electrode provided on one of both the surfaces of the buffer layer on the same side as the surface thereof on which the semiconductor layer has undergone crystal growth; and
a second electrode that is provided on one of both the surfaces of the semiconductor layer opposite to the surface thereof that has undergone crystal growth to become the light wavelength conversion member and that makes the semiconductor layer emit light by applying a voltage between the first electrode and the second electrode.

26. The light emitting module according to claim 24 further comprising:
a first electrode provided on one of both the surfaces of the buffer layer opposite to the surface thereof on which the semiconductor layer has undergone crystal growth; and
a second electrode that is provided on one of both the surfaces of the semiconductor layer opposite to the surface thereof that has undergone crystal growth to become the light wavelength conversion member and that makes the semiconductor layer emit light by applying a voltage between the first electrode and the second electrode, wherein
the buffer layer is formed on the first electrode.

27. The light emitting module according to claim 24 further comprising an electrode that has been provided between the buffer layer and the light wavelength conversion member and that has translucency.

28. A method of manufacturing a light emitting module comprising:
forming a buffer layer having translucency on a plate-shaped light wavelength conversion member that converts the wavelength of the light within a certain wavelength range and emits the light; and
making a semiconductor layer that emits the light containing at least part of the certain wavelength range by being applied with a voltage undergo crystal growth on the buffer layer.

29. The method of manufacturing a light emitting module according to claim 28 further comprising forming, on one of the surfaces of the semiconductor layer opposite to the surface thereof that has undergone crystal growth to become the light wavelength conversion member, a pair of electrodes that make the semiconductor layer emit light by applying a voltage between them.

30. The method of manufacturing a light emitting module according to claim 28 further comprising:
providing a first electrode so as to be adjacent to the light wavelength conversion member; and
forming, on one of both the surfaces of the semiconductor layer opposite to the surface thereof that has undergone crystal growth to become the light wavelength conversion member, a second electrode that makes the semiconductor layer emit light by applying a voltage between the first electrode and the second electrode, wherein
the making the semiconductor layer undergo crystal growth includes making the semiconductor layer undergo crystal growth on the first electrode.

31. The method of manufacturing a light emitting module according to claim 28, wherein
the buffer layer is formed of a conductive material and is provided so as to be capable of applying a voltage for light emission to the semiconductor layer.

32. The method of manufacturing a light emitting module according to claim 31 further comprising:
forming a first electrode on one of both the surfaces of the buffer layer on the same side as the surface thereof on which the semiconductor layer has undergone crystal growth; and
forming, on one of both the surfaces of the semiconductor layer opposite to the surface thereof that has undergone crystal growth to become the light wavelength conversion member, a second electrode that makes the semiconductor layer emit light by applying a voltage between the first electrode and the second electrode.

33. The method of manufacturing a light emitting module according to claim 31 further comprising:
providing a first electrode so as to be adjacent to the light wavelength conversion member; and
forming, on one of both the surfaces of the semiconductor layer opposite to the surface thereof that has undergone crystal growth to become the light wavelength conversion member, a second electrode that makes the semiconductor layer emit light by applying a voltage between the first electrode and the second electrode, wherein
the forming the buffer layer includes forming the buffer layer on the first electrode.

34. The method of manufacturing a light emitting module according to claim 31 further comprising forming an electrode having translucency between the buffer layer and the light wavelength conversion member.
